(19) United States
(12) Patent Application Publication
(10) Pub. No.: US 2025/0176261 A1
(43) Pub. Date: May 29, 2025

(54) INTEGRATED CIRCUIT INCLUDING ISLAND POWER TAP CELL

(71) Applicant: SAMSUNG ELECTRONICS CO., LTD., Suwon-si (KR)

(72) Inventors: Seunghoon Kang, Suwon-si (KR); Jooyeon Kwon, Suwon-si (KR)

(21) Appl. No.: 18/762,325

(22) Filed: Jul. 2, 2024

(30) Foreign Application Priority Data
Nov. 23, 2023 (KR) 10-2023-0164839

(51) Int. Cl. H01L 27/118

(52) U.S. Cl. CPC H10D 84/907; H10D 84/953; H10D 84/975; H10D 84/981

(57) ABSTRACT

An integrated circuit includes a plurality of active patterns including first and second active patterns each extending in a first direction and spaced apart from each other in a second direction intersecting with the first direction, a front wiring layer arranged above a front side of a substrate, a back wiring layer arranged on a backside of the substrate, and an island power tap cell arranged above the front side of the substrate. The island power tap cell includes first and second termination cells spaced apart from each other in the second direction, and a power tap cell arranged between the first and second termination cells and electrically connecting the back wiring layer to the front wiring layer. The first active pattern is cut above the first termination cell, and the second active pattern is cut above the second termination cell.

### CROSS-REFERENCE TO RELATED APPLICATION

This application claims priority under 35 U.S.C. § 119 to Korean Patent Application No. 10-2023-0164839, filed on Nov. 23, 2023, in the Korean Intellectual Property Office, the disclosure of which is incorporated by reference herein in its entirety.

### BACKGROUND

Widths, intervals, and/or heights of wires included in integrated circuits may be reduced due to demand for high integration and advancement in semiconductor processes, and the influence of parasitic components of wires may increase. Also, power supply voltages of the integrated circuits may be reduced to reduce power consumption and increase operating speed and so on, and accordingly, the influence of parasitic components of wires on the integrated circuits may be more significant. Accordingly, there is an increase in demand for a method of designing integrated circuits that efficiently routes wires and vias.

### SUMMARY

The disclosure provides an integrated circuit that may reduce routing complexity by using a front wiring layer and a back wiring layer and improve a power performance area (PPA) by arranging an island power tap cell and a method of designing the integrated circuit.

According to an aspect of the disclosure, an integrated circuit includes a plurality of active patterns including first and second active patterns each extending in a first direction and spaced apart from each other in a second direction intersecting with the first direction, a front wiring layer arranged above a front side of a substrate, a back wiring layer arranged on a backside of the substrate, and an island power tap cell arranged on the front side of the substrate, wherein the island power tap cell includes first and second termination cells spaced apart from each other in the second direction, and a power tap cell arranged between the first and second termination cells and electrically connecting the back wiring layer to the front wiring layer, and the first active pattern is cut above the first termination cell, and the second active pattern is cut above the second termination cell.

Also, according to another aspect of the disclosure, an integrated circuit includes a plurality of active patterns including first and second active patterns each extending in a first direction and spaced apart from each other in a second direction intersecting with the first direction, a front wiring layer arranged above a front side of a substrate, a back wiring layer arranged on a backside of the substrate, first inline power tap cells arranged in a row in the second direction, second inline power tap cells arranged in a row in the second direction and spaced apart from the first inline power tap cells in the first direction, and an island power tap cell arranged between the first inline power tap cells and the second inline power tap cells, wherein the island power tap cell comprises first and second termination cells spaced apart from each other in the second direction, and a power tap cell arranged between the first and second termination cells and electrically connecting the back wiring layer to the front wiring layer, and the first active pattern is cut above the first termination cell, and the second active pattern is cut above the second termination cell.

Furthermore, according to another aspect of the disclosure, an integrated circuit includes a front wiring layer arranged above a front side of a substrate and including front wiring lines extending in a first direction, a back wiring layer arranged on a backside of the substrate, first inline power tap cells arranged in a row in a second direction intersecting with the first direction, second inline power tap cells arranged in a row in the second direction and spaced apart from the first inline power tap cells in the first direction, a first island power tap cell arranged between the first inline power tap cells and the second inline power tap cells, and a second island power tap cell arranged between the first inline power tap cells and the second inline power tap cells, wherein a height of the first island power tap cell in the second direction is different from a height of the second island power tap cell in the second direction.

### BRIEF DESCRIPTION OF THE DRAWINGS

Implementations of the disclosure will be more clearly understood from the following detailed description taken in conjunction with the accompanying drawings in which:

FIG. 1 illustrates a layout of an integrated circuit according to some implementations;

FIG. 2 is a perspective view illustrating part of the integrated circuit of FIG. 1 according to some implementations;

FIG. 3A illustrates an example of a cross-sectional view taken along line X1-X1′ of FIG. 1 according to some implementations, FIG. 3B illustrates another example of the cross-sectional view taken along line X1-X1′ of FIG. 1 according to some implementations, and FIG. 3C illustrates another example of the cross-sectional view taken along line X1-X1′ of FIG. 1 according to some implementations;

FIG. 4 illustrates a cross-sectional view taken along line X2-X2′ of FIG. 1 according to some implementations;

FIG. 5 illustrates a cross-sectional view taken along line X3-X3′ of FIG. 1 according to some implementations;

FIG. 6 illustrates a layout of an integrated circuit according to some implementations;

FIG. 7 illustrates a layout of an integrated circuit according to some implementations;

FIG. 8 illustrates a layout of an integrated circuit according to some implementations;

FIG. 9 illustrates a layout of an integrated circuit according to some implementations;

FIG. 10 illustrates a layout of an integrated circuit according to some implementations;

FIG. 11 illustrates a first layout and a second layout according to some implementations;

FIG. 12 illustrates a first layout and a second layout according to some implementations;

FIGS. 13A to 13D illustrate devices according to some embodiments;

FIG. 14 is a flowchart illustrating a method of manufacturing an integrated circuit, according to some implementations;

FIG. 15 is a block diagram illustrating a system-on-chip according to some implementations; and

FIG. 16 is a block diagram illustrating a computing system including a memory for storing a program, according to some implementations.

### DETAILED DESCRIPTION

Hereinafter, implementations of the disclosure are described in detail with reference to the attached drawings. The same reference numerals are used for the same components in the drawings, and redundant descriptions thereof are omitted.

In the disclosure, an X-axis direction may be referred to as a first horizontal direction or a first direction, and a Y-axis direction may be referred to as a second horizontal direction or a second direction, and a Z-axis direction may be referred to as a vertical direction. A plane formed by X and Y axes may be referred to as a horizontal plane, a component arranged in the +Z-axis direction relatively to other components may be referred to as being above another component, and a component arranged in the-Z-axis direction relatively to other components may be referred to as being below other components.

An integrated circuit may be designed by arranging a plurality of standard cells. The standard cell is a unit of layout of an integrated circuit and may be referred to as a “cell” depending on implementations. The standard cell may be designed to include a plurality of transistors to perform a predefined function. A standard cell method of designing a large-scale integrated circuit used for only a customer or user prepares standard cells with various functions in advance and combines the standard cells with each other. The standard cells are designed and verified in advance and registered in a standard cell library, and computer-aided design (CAD) is used to perform logical design, placement, and routing by combining the standard cells, and accordingly, integrated circuits may be designed. When designing the integrated circuits, lengths of wires and/or vias and routing complexity are reduced, and accordingly, the performance of integrated circuits may be further increased.

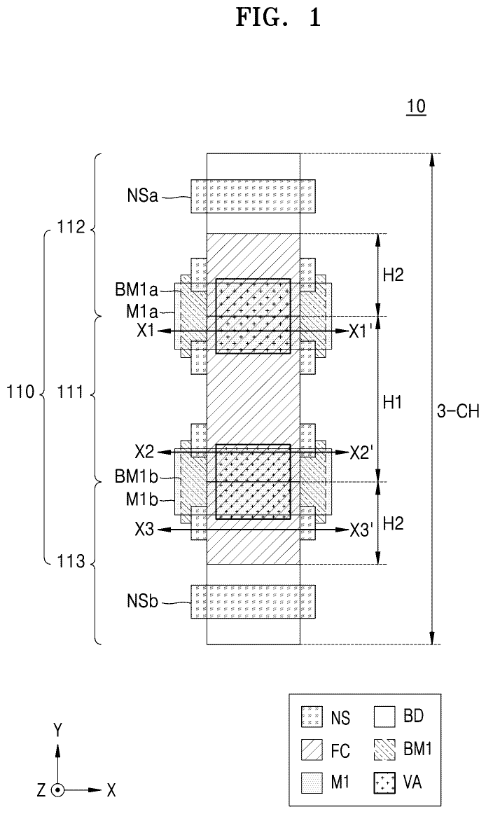

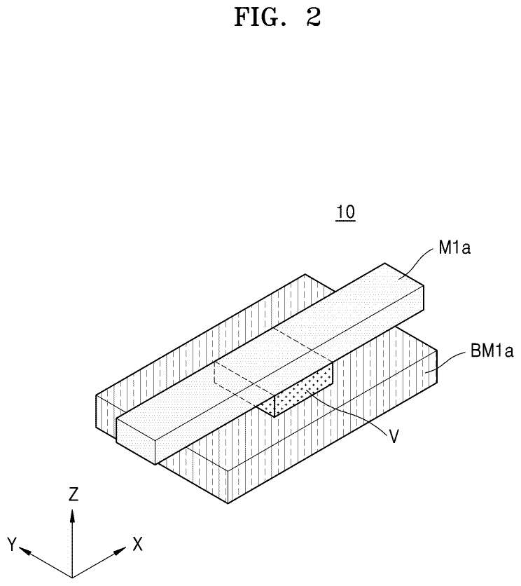

FIG. 1 illustrates a layout of an integrated circuit 10 according to some implementations.

Referring to FIG. 1, the integrated circuit 10 includes an island power tap cell (PTC) 110 of an island type. According to some implementations, the island power tap cell 110 may be referred to as an island small power tap cell (small PTC or sPTC). The island power tap cell 110 may be implemented as a multi height cell. For example, the island power tap cell 110 includes a power tap cell 111, a first terminate cell or a first termination cell 112, and a second terminate cell or a second termination cell 113, and may be implemented in a height corresponding to a 3-cell height (CH) 3-CH. Each of the power tap cell 111 and the first and second termination cells 112 and 113 may be defined by a cell boundary BD.

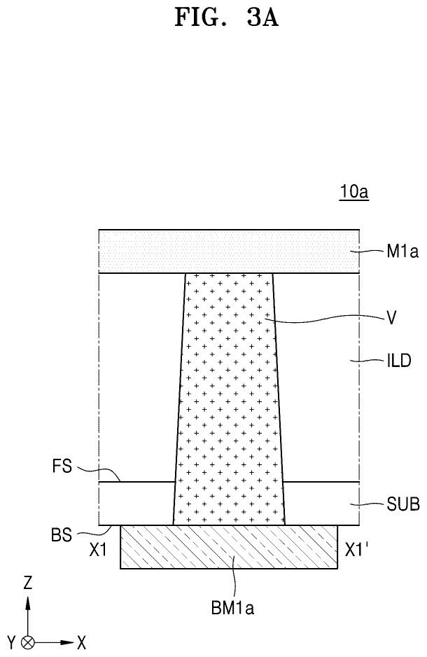

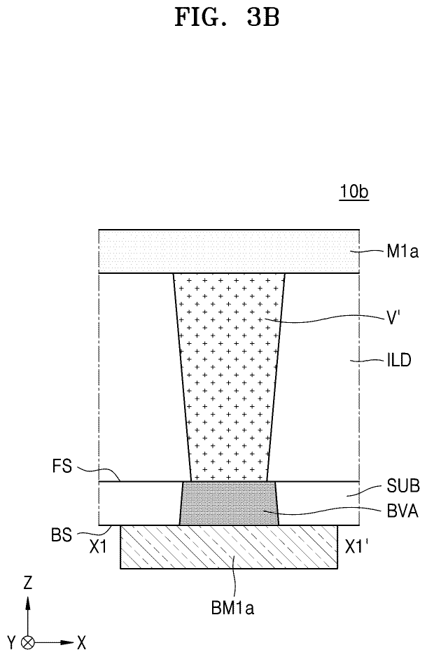

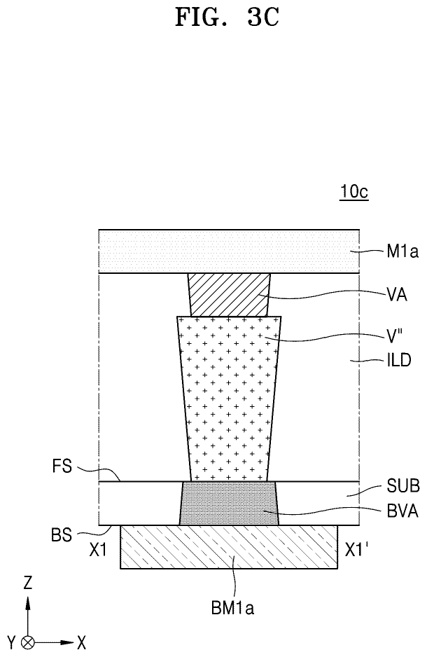

The integrated circuit 10 may be implemented by a semiconductor device, and a substrate on which the semiconductor device is formed may have a first surface or first side (e.g., FS in FIG. 3A) and a second surface or second side (e.g., BS in FIG. 3A). For example, the first surface may be a surface on which circuit elements, such as transistors, are arranged, and in the disclosure, the first surface may be referred to as a “front surface” or “front side.” The second surface may be a surface opposite to the first surface, and the second surface may be referred to herein as a “back surface” or “backside.”

The integrated circuit 10 includes a front side wiring layer or front wiring layer M1 and a backside wiring layer or back wiring layer BM1 and may constitute a power distribution network PDN by using the front wiring layer M1 and the back wiring layer BM1. In this case, the front wiring layer M1 may be above the island power tap cell 110 in a vertical direction Z, and the back wiring layer BM1 may be below the island power tap cell 110 in the vertical direction Z. Accordingly, some of signals and/or electrical power applied to the integrated circuit 10 may be transferred through the front wiring layer M1, that is, a front side PDN (FSPDN), and the other thereof may be transferred through the back wiring layer BM1, that is, a backside PDN (BSPDN). Therefore, according to the illustrated implementations, routing complexity may be greatly reduced and lengths of respective wires or vias may also be reduced compared to a structure in which wires are arranged only above a front surface of a substrate, and thus, the performance of the integrated circuit 10 may be increased.

For example, the front wiring layer M1 includes first and second front wiring lines M1a and M1b, each extending in the first direction X and being spaced apart from each other in the second direction Y. According to some implementations, the first and second front wiring lines M1a and M1b may also be referred to respectively as first and second power rails. For example, the back wiring layer BM1 includes first and second back wiring patterns BM1a and BM1b, each extending in the first direction X and being spaced apart from each other in the second direction Y. However, the disclosure is not limited thereto, and extension directions and arrangements of the first and second front wiring lines M1a and M1b and/or the first and second back wiring patterns BM1a and BM1b may be changed in various ways depending on implementations.

The integrated circuit 10 may include a plurality of active patterns, each extending in the first direction X and being spaced apart from each other in the second direction Y. For example, the plurality of active patterns are diffusion regions doped with impurities that change the electrical properties of a substrate material and may form source/drain regions of transistors. In some implementations, the plurality of active patterns may correspond to nanosheets NS, and in this case, the integrated circuit 10 may include multi-bridge channel field effect transistors (MBCFETs). However, the disclosure is not limited thereto, and in some implementations, the plurality of active patterns may correspond to nanowires, and in this case, the integrated circuit 10 may include gate-all-around field effect transistors (GAAFETs). Also, in some implementations, the plurality of active patterns may correspond to fin structures or fins, and in this case, the integrated circuit 10 may include FinFETs.

The integrated circuit 10 may further include a cutting region or cutting layer FC for cutting some active patterns. The cutting layer FC may overlap a partial region of the first termination cell 112, the power tap cell 111, and a partial region of the second termination cell 113. For example, the power tap cell 111 and the first and second termination cells 112 and 113 may each have a first height H1 in the second direction Y, and the cutting layer FC may have a height (that is, 2*H1) corresponding to twice the first height H1 in the second direction Y. For example, the cutting layer FC may overlap the power tap cell 111 by the first height H1, overlap the first termination cell 112 by a second height H2, and overlap the second termination cell 113 by the second height H2. For example, the second height H2 may be half of the first height H1 but is not limited thereto.

The nanosheets NS overlapping the power tap cell 111 may be cut by the cutting layer FC. Among the nanosheets NS overlapping the first termination cell 112, the nanosheet NS that is adjacent to the power tap cell 111 may be cut by the cutting layer FC. Among the nanosheets NS overlapping the second termination cell 113, the nanosheet NS that is adjacent to the power tap cell 111 may be cut by the cutting layer FC. In addition, a nanosheet NSa overlapping the first termination cell 112 and a nanosheet NSb overlapping the second termination cell 113 may be used as dummy nanosheets or dummy patterns. However, the disclosure is not limited thereto, and in some implementations, the nanosheets NSa and NSb may also be cut by the cutting layer FC.

The power tap cell 111 may electrically connect the back wiring layer BM1 to the front wiring layer M1 and transfer a positive or negative supply voltage from the back wiring layer BM1 to the front wiring layer M1. According to some implementations, the power tap cell 111 may be referred to as a “power pickup cell”, a “pickup cell”, or a “tap cell.” Hereinafter, a structure of the power tap cell 111 is described in more detail with reference to FIG. 2.

FIG. 2 is a perspective view schematically illustrating a partial region of the integrated circuit 10 of FIG. 1 according to some implementations.

Referring to FIGS. 1 and 2 together, the power tap cell 111 includes a via pattern or a via V extending in the vertical direction Z. The via V may extend in the vertical direction Z between the back wiring layer BM1 and the front wiring layer M1 and electrically connect the back wiring layer BM1 to the front wiring layer M1. According to some implementations, the via V may be referred to as a through-via. For example, the via V may extend in the vertical direction Z between a first back wiring pattern BM1a and a first front wiring line M1a and may electrically connect the first back wiring pattern BM1a to the first front wiring line M1a.

FIG. 1 illustrates that the power tap cell 111 includes two vias V. For example, the first back wiring pattern BM1a may receive a positive supply voltage, such as, a power supply voltage, and the second back wiring pattern BM1b may receive a negative supply voltage, such as a ground voltage. In this case, the power tap cell 111 may transfer a power supply voltage from the first back wiring pattern BM1a to the first front wiring line M1a through the via V and transfer a ground voltage from the second back wiring pattern BM1b to the second front wiring line M1b through the via V. However, the disclosure is not limited thereto, and in some implementations, the power tap cell 111 may include one via V. In this case, the power tap cell 111 may transfer the power supply voltage or ground voltage from the back wiring layer BM1 to the front wiring layer M1 through the via V.

FIG. 3A illustrates an example of a cross-sectional view taken along line X1-X1′ of FIG. 1 according to some implementations.

Referring to FIGS. 1 and 3A together, a substrate SUB may include a semiconductor substrate having a front side FS and a backside BS. For example, the semiconductor substrate may include any one of silicon, a silicon-on-insulator (SOI), silicon-on-sapphire, germanium, silicon-germanium, and gallium-arsenide. An interlayer insulating layer ILD may be on the substrate SUB. The interlayer insulating layer ILD may include an insulating material, and for example, the insulating material may include any one of an oxide layer, a nitride layer, and an oxynitride layer.

In some implementations, the substrate SUB may correspond to a bulkless substrate. During a process of manufacturing an integrated circuit 10a, a device wafer may be fabricated by forming gate lines, source/drain regions, contacts, vias, and/or wiring layers on a front side FS of the substrate SUB. Subsequently, a device wafer may be temporarily bonded to a carrier wafer, and a back-grinding process may be performed on the device wafer to remove at least part of the substrate. In this way, a wafer that is back-grinded such that the height of the substrate is a reference height or less may be referred to as a “bulkless wafer” or a “bulkless substrate.”

The first back wiring pattern BM1a may extend from the backside BS of the substrate SUB in the first direction X. The first front wiring line M1a may extend in the first direction X on the interlayer insulating layer ILD. However, the disclosure is not limited thereto, and extension directions of the first back wiring pattern BM1a and the first front wiring line M1a may change depending on implementations. A lower surface of the via V may be in contact with the first back wiring pattern BM1a, and an upper surface of the via V may be in contact with the first front wiring line M1a.

FIG. 3B illustrates another example of the cross-sectional view taken along line X1-X1′ of FIG. 1 according to some implementations.

Referring to FIGS. 1 and 3B together, an integrated circuit 10b corresponds to a modification example of the integrated circuit 10a of FIG. 3A, and the description made above with reference to FIG. 3A may also be applied to the illustrated implementations. For example, the power tap cell 111 includes a back via BVA and a via V′. The back via BVA may be on the first back wiring pattern BM1a and may extend in the vertical direction Z through the substrate SUB. The via V′ may be on the back via BVA and may extend in the vertical direction Z through the interlayer insulating layer ILD. Accordingly, the first back wiring pattern BM1a may be electrically connected to the first front wiring line M1a through the back via BVA and via V′.

FIG. 3C illustrates another example of the cross-sectional view taken along line X1-X1′ of FIG. 1 according to some implementations.

Referring to FIGS. 1 and 3C together, an integrated circuit 10c may correspond to a modification example of the integrated circuit 10a of FIG. 3A, and the description made above with reference to FIG. 3A may also be applied to the illustrated implementations. For example, the power tap cell 111 includes a back via BVA, a via V″, and a first via VA. The back via BVA may be on the first back wiring pattern BM1a and extend in the vertical direction Z through the substrate SUB. The via V″ may be on the back via BVA and extend in the vertical direction Z through the interlayer insulating layer ILD. The first via VA may be on the via V″ and extend in the vertical direction Z through the interlayer insulating layer ILD. Accordingly, the first back wiring pattern BM1a may be electrically connected to the first front wiring line M1a through the back via BVA, via V″, and first via VA.

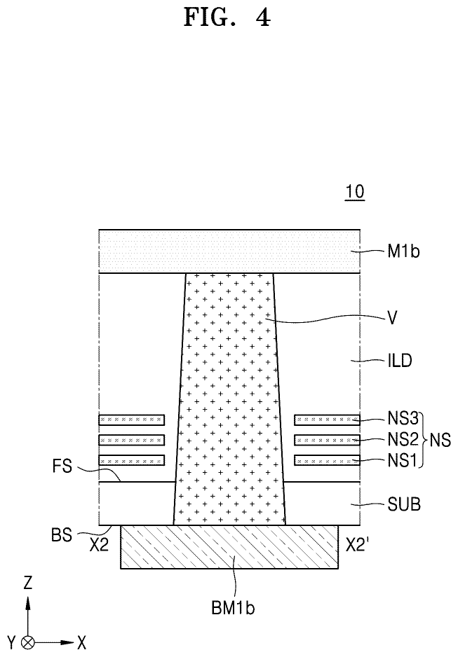

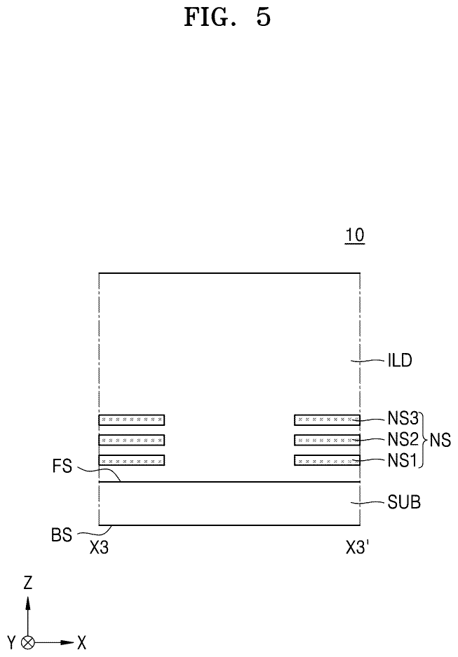

FIG. 4 illustrates a cross-sectional view taken along line X2-X2′ of FIG. 1 according to some implementations. FIG. 5 illustrates a cross-sectional view taken along line X3-X3′ of FIG. 1 according to some implementations.

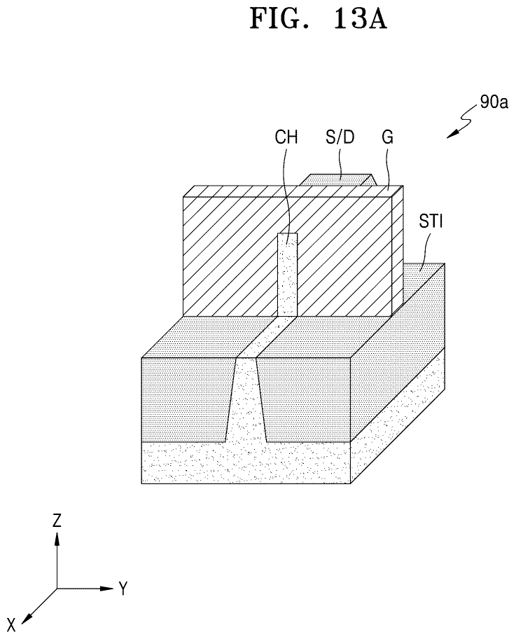

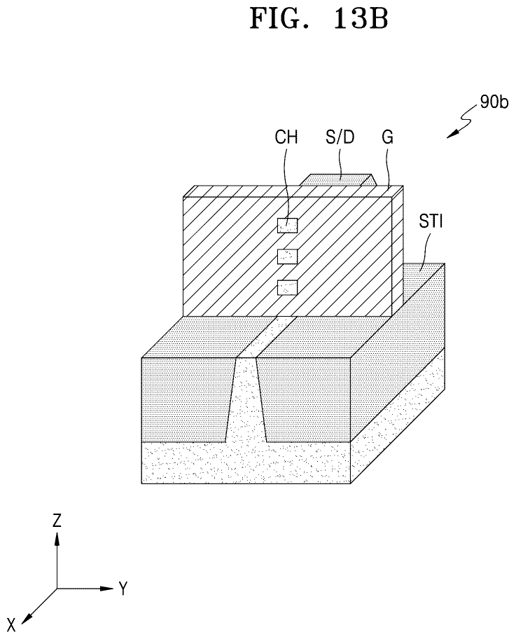

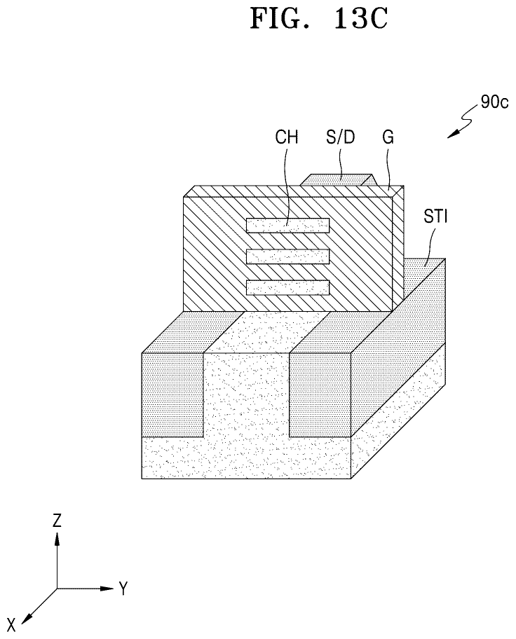

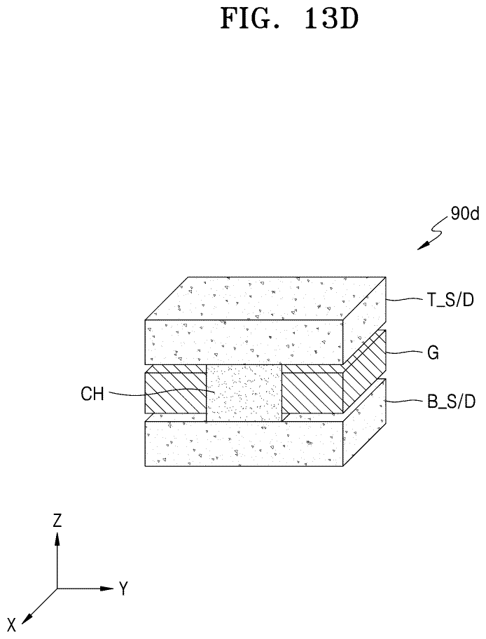

FIGS. 4 and 5 illustrate examples of nanosheets formed on an active region. For example, an MBCFET may be formed in which a plurality of nanosheets are stacked on an active region and a gate line surrounds the plurality of nanosheets. However, an integrated circuit according to the disclosure is not limited to the illustrations in FIGS. 4 and 5. For example, a FinFET, which includes a fin and a gate line formed on the active region, may also be formed. In another example, a GAAFET may also be formed in which nanowires formed on the active region are surrounded by a gate line. This is described in more detail with reference to FIGS. 13A to 13D.

Referring to FIGS. 1, 4, and 5 together, a nanosheet stack or nanosheet NS extending in the first direction X may be above the front side FS of the substrate SUB. The nanosheet stack or nanosheet NS may include a plurality of nanosheets overlapping in the vertical direction Z, for example, first, second, and third nanosheets (NS1, NS2, and NS3). For example, the nanosheet NS above an N well may be doped with an N-type impurity and form an N-type transistor. In addition, the nanosheet NS above a P-type substrate may be doped with a P-type impurity and form a P-type transistor. In some implementations, the nanosheet NS may include Si, Ge, or SiGe. In some implementations, the nanosheet NS may include InGaAs, InAs, GaSb, InSb, or a combination thereof.

As illustrated in FIG. 4, the nanosheet NS may be cut by the cutting layer FC overlapping the power tap cell 111, and the via V may extend in the vertical direction Z in a region where the nanosheet NS is removed. In addition, as illustrated in FIG. 5, the nanosheet NS may be cut by the cutting layer FC overlapping the second termination cell 113. In this way, the nanosheets NS may be cut by the cutting layer FC overlapping the first and second termination cells 112 and 113, and thus, standard cells or logic cells may be freely placed on the top or bottom of the island power tap cell 110.

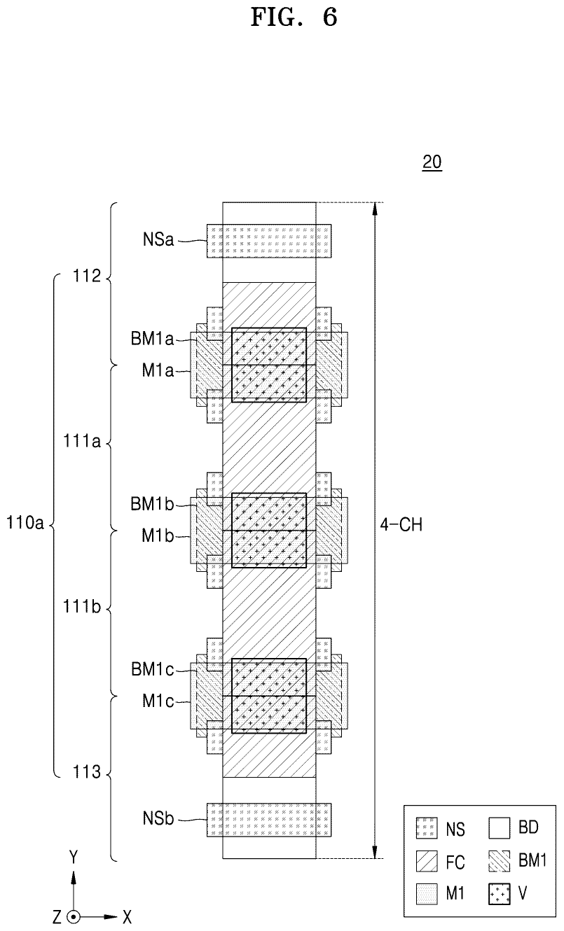

FIG. 6 illustrates a layout of an integrated circuit 20 according to some implementations.

Referring to FIG. 6, the integrated circuit 20 includes an island power tap cell 110a. The integrated circuit 20 may correspond to a modification example of the integrated circuit 10 of FIG. 1, and the description made above with reference to FIGS. 1 to 5 may also be applied to the illustrated implementations. For example, the island power tap cell 110a includes first and second power tap cells 111a and 111b and first and second termination cells 112 and 113, thereby being implemented in a height corresponding to a 4-CH.

A front wiring layer M1 includes first, second, and third front wiring lines M1a, M1b, and M1c extending in the first direction X. A back wiring layer BM1 includes first, second, and third back wiring patterns BM1a, BM1b, and BM1c extending in the first direction X. A cutting layer FC may overlap a partial region of the first termination cell 112, the first and second power tap cells 111a and 111b, and a partial region of the second termination cell 113. For example, the first and second power tap cells 111a and 111b and the first and second termination cells 112 and 113 may each have a first height H1 in the second direction Y, and the cutting layer FC may have a height (that is, 3*H1) corresponding to three times the first height H1 in the second direction Y.

Nanosheets NS overlapping the first power tap cell 111a may be cut by the cutting layer FC. Nanosheets NS overlapping the second power tap cell 111b may be cut by the cutting layer FC. Among the nanosheets NS overlapping the first termination cell 112, the nanosheet NS that is adjacent to the first power tap cell 111a may be cut by the cutting layer FC. Among the nanosheets NS overlapping the second termination cell 113, the nanosheet NS that is adjacent to the second power tap cell 111b may be cut by the cutting layer FC. In addition, a nanosheet NSa overlapping the first termination cell 112 and a nanosheet NSb overlapping the second termination cell 113 may be used as dummy nanosheets or dummy patterns. However, the disclosure is not limited thereto, and in some implementations, the nanosheets NSa and NSb may also be cut by the cutting layer FC.

FIG. 7 illustrates a layout of an integrated circuit 30 according to some implementations.

Referring to FIG. 7, the integrated circuit 30 includes an island power tap cell 110b. The integrated circuit 30 may correspond to a modification example of the integrated circuit 10 of FIG. 1, and the description made above with reference to FIGS. 1 to 5 may also be applied to the illustrated implementations. For example, the island power tap cell 110b includes first, second, and third power tap cells 111a, 111b, and 111c and first and second termination cells 112 and 113, thereby being constituted in a height corresponding to a 5-CH.

A front wiring layer M1 includes first, second, third, and fourth front wiring lines M1a, M1b, M1c, and M1d extending in the first direction X. A back wiring layer BM1 includes first, second, third, and fourth back wiring patterns BM1a, BM1b, BM1c, and BM1d extending in the first direction X. A cutting layer FC may overlap a partial region of the first termination cell 112, the first, second, and third power tap cells 111a, 111b, and 111c, and a partial region of the second termination cell 113. For example, the first, second, and third power tap cells 111a, 111b, and 111c and the first and second termination cells 112 and 113 may each have a first height H1 in the second direction Y, and the cutting layer FC may have a height (that is, 4*H1) corresponding to four times the first height H1 in the second direction Y.

Nanosheets NS overlapping the first power tap cell 111a may be cut by the cutting layer FC. Nanosheets NS overlapping the second power tap cell 111b may be cut by the cutting layer FC. Nanosheets NS overlapping the third power tap cell 111c may be cut by the cutting layer FC. Among the nanosheets NS overlapping the first termination cell 112, the nanosheet NS that is adjacent to the first power tap cell 111a may be cut by the cutting layer FC. Among the nanosheets NS overlapping the second termination cell 113, the nanosheet NS that is adjacent to the third power tap cell 111c may be cut by the cutting layer FC. In addition, a nanosheet NSa overlapping the first termination cell 112 and a nanosheet NSb overlapping the second termination cell 113 may be used as dummy nanosheets or dummy patterns. However, the disclosure is not limited thereto, and in some implementations, the nanosheets NSa and NSb may also be cut by the cutting layer FC.

As illustrated in FIGS. 1, 6, and 7, the number of power tap cells included in an island power tap cell may change depending on implementations, and accordingly, the height of the island power tap cell may change in various ways depending on implementations. In this way, according to implementations of the disclosure, considering power consumption according to a function of an integrated circuit, the number of power tap cells included in an island power tap cell may be increased or decreased.

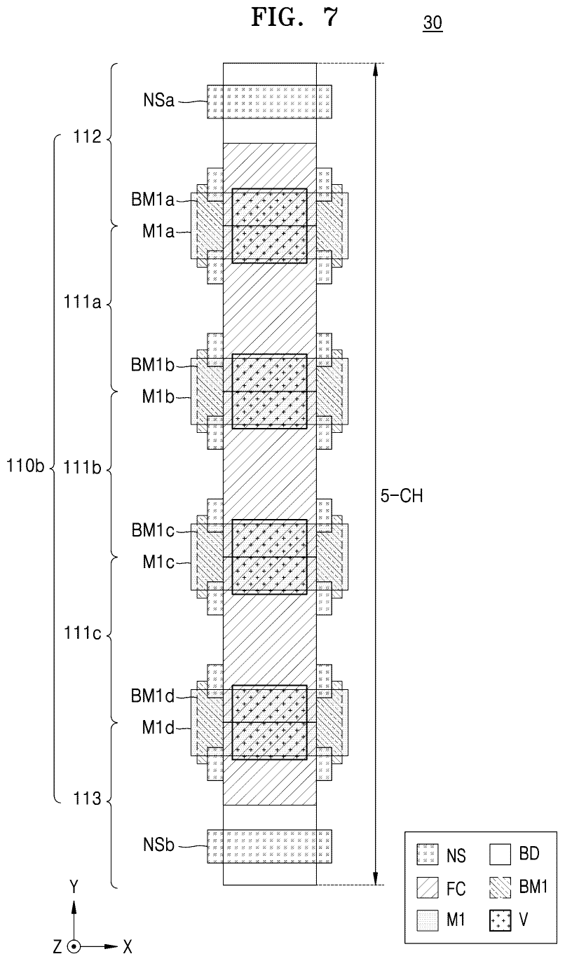

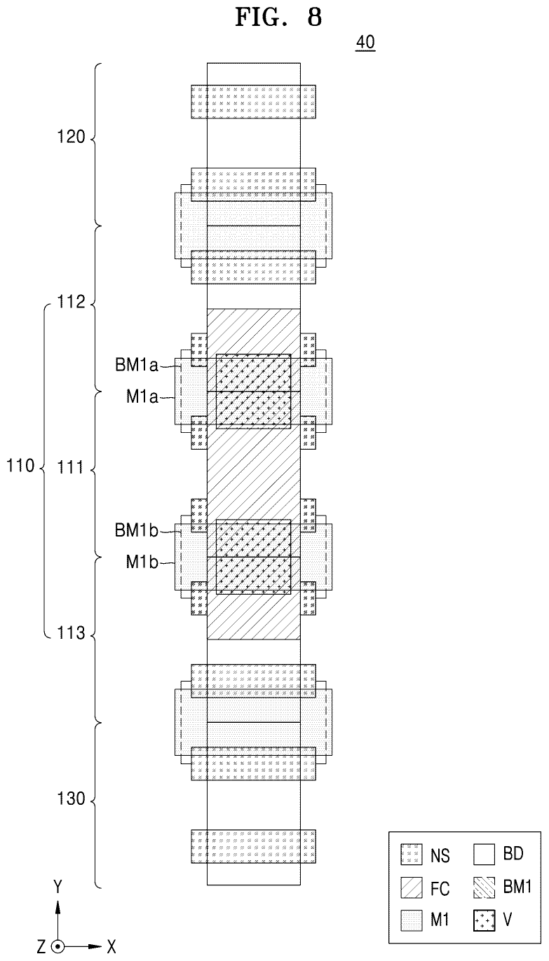

FIG. 8 illustrates a layout of an integrated circuit 40 according to some implementations.

Referring to FIG. 8, the integrated circuit 40 includes an island power tap cell 110 and first and second logic cells 120 and 130. For example, the island power tap cell 110 includes a power tap cell 111 and first and second termination cells 112 and 113. However, the disclosure is not limited thereto, and the island power tap cell 110 may include a plurality of power tap cells between the first and second termination cells 112 and 113. The description made above with reference to FIGS. 1 to 7 may also be applied to the illustrated implementations. For example, the first and second logic cells 120 and 130 may be implemented as various components, such as standard cells, blocks, macros, or memories.

When only the power tap cell 111 is between the first and second logic cells 120 and 130, a design rule violation may occur. For example, due to the placement of the power tap cell 111, a lower active pattern among active patterns included in the first logic cell 120 may be required to be cut by a cutting layer, and an upper active pattern among the active patterns included in the first logic cells 120 may be used only as a dummy pattern. Likewise, due to the arrangement of the power tap cell 111, an upper active pattern among the active patterns included in the second logic cell 130 may be required to be cut by a cutting layer, and a lower active pattern among the active patterns included in the second logic cell 130 may be used only as a dummy pattern. Accordingly, in the related art, a plurality of power tap cells may only be arranged in an inline shape.

However, according to some implementations, the integrated circuit 40 includes the island power tap cell 110 in which the first termination cell 112 is place on the top of the power tap cell 111 and the second termination cell 113 is placed on the bottom of the power tap cell 111. In this way, the first termination cell 112 is between the first logic cell 120 and the power tap cell 111, and accordingly, the arrangement of a cutting layer for the first logic cell 120 may not be required. Likewise, the second termination cell 113 is between the second logic cell 130 and the power tap cell 111, and accordingly, the arrangement of a cutting layer for the second logic cell 130 may not be required. Accordingly, a design rule violation for the integrated circuit 40 may not occur, and the first and second logic cells 120 and 130 may be freely placed on the top and bottom of the island power tap cell 110.

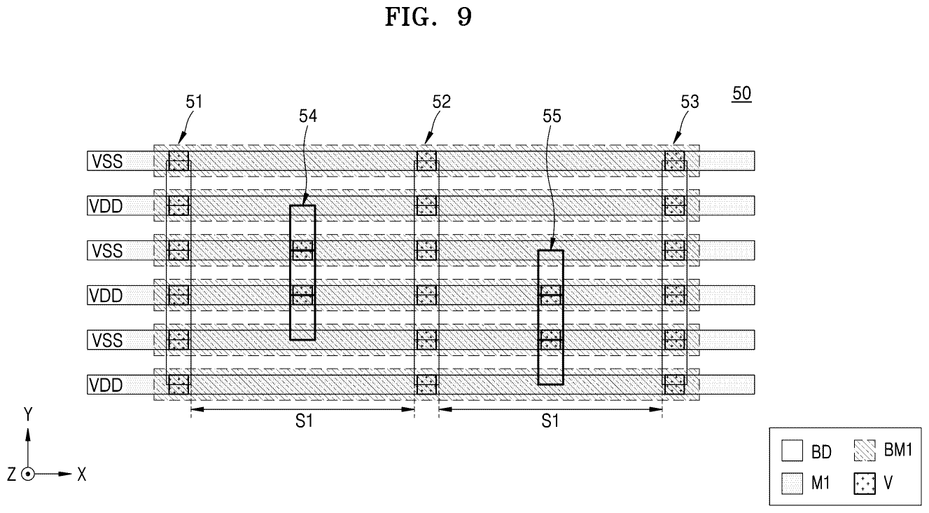

FIG. 9 illustrates a layout of an integrated circuit 50 according to some implementations.

Referring to FIG. 9, the integrated circuit 50 includes first, second, and third inline power tap cells 51, 52, and 53 and first and second island power tap cells 54 and 55. Also, the integrated circuit 50 includes a front wiring layer M1 and a back wiring layer BM1. Furthermore, the integrated circuit 50 may further include active regions, gate lines, source/drains, and contacts, and the gate lines and source/drains may receive power and/or signals from the front wiring layer M1 and the back wiring layer BM1 through the contacts.

The first, second, and third inline power tap cells 51, 52, and 53 and the first and second island power tap cells 54 and 55 may each include a via V, and the via V may extend in the vertical direction Z to electrically connect the front wiring layer M1 to the back wiring layer BM1. For example, the front wiring layer M1 may include front wiring lines that each receive a positive supply voltage or power supply voltage VDD or a negative supply voltage or ground voltage VSS arranged alternately, but the disclosure is not limited thereto.

The first inline power tap cells 51 may include a plurality of power tap cells arranged in a row in the second direction Y. The second inline power tap cells 52 may include a plurality of power tap cells arranged in a row in the second direction Y. The third inline power tap cells 53 may include a plurality of power tap cells arranged in a row in the second direction Y. For example, the first inline power tap cells 51 and the second inline power tap cells 52 may be spaced apart from each other by a first space S1 in the first direction X, and the second inline power tap cells 52 and the third inline power tap cells 53 may be spaced apart from each other by the first space S1 in the first direction X.

A plurality of logic cells or a plurality of standard cells may be placed between the first inline power tap cells 51 and the second inline power tap cells 52, and the plurality of logic cells or the plurality of standard cells may receive the power supply voltage VDD or the ground voltage VSS through the back wiring layer BM1, the first inline power tap cells 51, and the front wiring layer M1 or receive the power supply voltage VDD or the ground voltage VSS through the back wiring layer BM1, the second inline power tap cells 52, and the front wiring layer M1. In this case, as the first space S1 increases, a voltage transmission path for some cells among the plurality of logic cells or the plurality of standard cells increases, and accordingly, an IR-drop issue may occur. According to some implementations, the first island power tap cell 54 may be in an IR-drop vulnerable region or an IR-drop hot spot, such as a section where IR-drop is expected to be great or a great IR-drop section. Accordingly, IR-drop for logic cells and/or standard cells that are adjacent to the first island power tap cell 54 may be reduced, and power may be stably supplied.

Likewise, a plurality of logic cells or a plurality of standard cells may be placed between the second inline power tap cells 52 and the third inline power tap cells 53, and the plurality of logic cells or the plurality of standard cells may receive the power supply voltage VDD or ground voltage VSS through the back wiring layer BM1, the second inline power tap cells 52, and the front wiring layer M1 or receive the power supply voltage VDD or ground voltage VSS through the back wiring layer BM1, the third inline power tap cells 53, and the front wiring layer M1. In this case, as the first space S1 increases, a voltage transmission path for some cells among the plurality of logic cells or the plurality of standard cells increases, and an IR-drop issue may occur. According to some implementations, the second island power tap cell 55 may be in an IR-drop vulnerable section or an IR-drop hot spot, such as a section in which IR-drop is expected to be great or a great IR-drop section. Accordingly, IR-drop for logic cells and/or standard cells that are adjacent to the second island power tap cell 55 may be reduced, and power may be stably supplied.

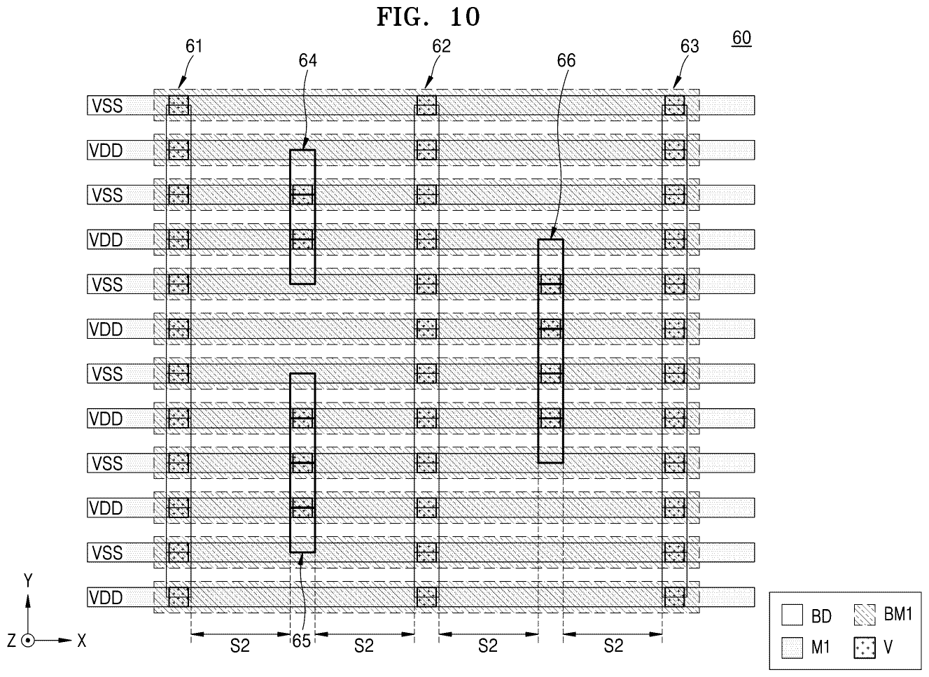

FIG. 10 illustrates a layout of an integrated circuit 60 according to some implementations.

Referring to FIG. 10, the integrated circuit 60 includes first, second, and third inline power tap cells 61, 62, and 63 and first, second, and third island power tap cells 64, 65, and 66. Also, the integrated circuit 60 includes a front wiring layer M1 and a back wiring layer BM1. The integrated circuit 60 may correspond to a modification example of the integrated circuit 50 of FIG. 9, and the description made above with reference to FIG. 9 may also be applied to the illustrated implementations.

The first, second, and third inline power tap cells 61, 62, and 63 and the first, second, and third island power tap cells 64, 65, and 66 may each include a via V, and the via V may extend in the vertical direction Z to electrically connect the front wiring layer M1 to the back wiring layer BM1. For example, the front wiring layer M1 may include front wiring lines that each receive a positive supply voltage or power voltage VDD or a negative supply voltage or ground voltage VSS arranged alternately but is not limited thereto.

The first inline power tap cells 61 may include a plurality of power tap cells arranged in a row in the second direction Y. The second inline power tap cells 62 may include a plurality of power tap cells arranged in a row in the second direction Y. The third inline power tap cells 63 may include a plurality of power tap cells arranged in a row in the second direction Y. Heights of the first, second, and third island power tap cells 64, 65, and 66 in the second direction Y may be different. For example, the first island power tap cell 64 may be constituted in a 3-CH including a power tap cell and two termination cells. For example, the second island power tap cell 65 may be constituted in a 4-CH including two power tap cells and two termination cells. For example, the third island power tap cell 66 may be constituted in a 5-CH including three power tap cells and two termination cells. In this way, according to the illustrated implementations, the integrated circuit 60 may include island power tap cells having different heights.

For example, the first island power tap cell 64 may be spaced apart from the first inline power tap cells 61 by a second space S2 in the first direction X and may be spaced apart from the second inline power tap cells 62 by the second space S2 in the first direction X. In this way, the first island power tap cell 64 may be in a center region or an intermediate region between the first inline power tap cells 61 and the second inline power tap cells 62, but the disclosure is not limited thereto.

For example, the second island power tap cell 65 may be spaced apart from the first inline power tap cells 61 by the second space S2 in the first direction X and may be spaced apart from the second inline power tap cells 62 by the second space S2 in the first direction X. In this way, the second island power tap cell 65 may be in a center region or an intermediate region between the first inline power tap cells 61 and the second inline power tap cells 62, but the disclosure is not limited thereto.

For example, the third island power tap cell 66 may be spaced apart from the second inline power tap cells 62 by the second space S2 in the first direction X and may be spaced apart from the third inline power tap cells 63 by the second space S2 in the first direction X. In this way, the third island power tap cell 66 may be in a center region or an intermediate region between the second inline power tap cells 62 and the third inline power tap cells 63, but the disclosure is not limited thereto.

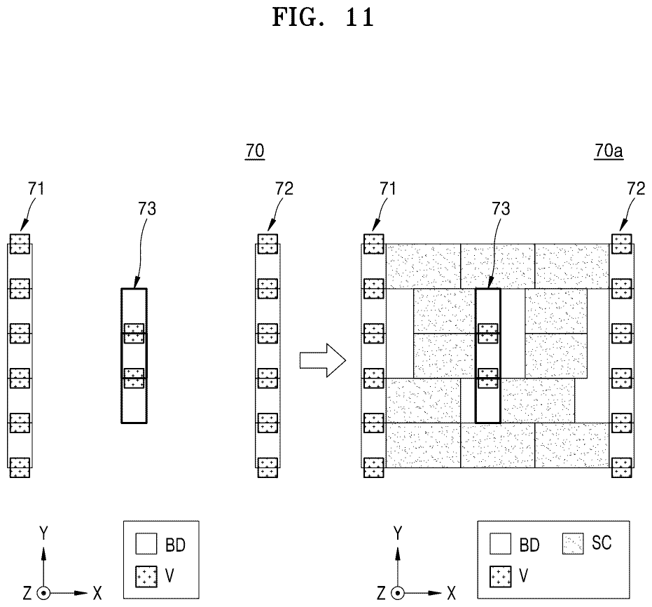

FIG. 11 illustrates a first layout 70 and a second layout 70a according to some implementations.

Referring to FIG. 11, a method of manufacturing an integrated circuit including standard cells SC may include a placement and routing (P&R) operation including a placement operation of placing the standard cells SC and a routing operation of routing pins of the standard cells SC. Before the standard cells are placed, the first layout 70 may be generated by placing first and second inline power tap cells 71 and 72 and an island power tap cell 73. Subsequently, by respectively placing the standard cells SC in a region between the first and second inline power tap cells 71 and 72, a region between the first inline power tap cells 71 and the island power tap cell 73, and a region between the second inline power tap cells 72 and the island power tap cell 73, the second layout 70a may be generated.

In some implementations, the island power tap cell 73 may be placed in advance in a section, in which IR-drop is expected to be vulnerable, between the first and second inline power tap cells 71 and 72. For example, an IR-drop vulnerable section may be expected based on a distance from the first inline power tap cells 71 and/or a distance from the second inline power tap cells 72, and island power tap cells may be placed in the expected IR-drop vulnerable section. For example, the IR-drop vulnerable section may be expected based on an interval between the first inline power tap cells 71 and the second inline power tap cells 72, and the island power supply tap cells may be placed in the expected IR-drop vulnerable section. For example, the IR-drop vulnerable section may be expected based on the number of power tap cells included in the first inline power tap cells 71 and/or the number of power tap cells included in the second inline power tap cells 72, and the island power tap cells may be placed in the expected IR-drop vulnerable section.

In some implementations, before the standard cells SC are placed, the island power tap cell 73 may be placed in advance at a center region or an intermediate region between the first and second inline power tap cells 71 and 72. Although FIG. 11 illustrates that one island power tap cell 73 is placed between the first and second inline power tap cells 71 and 72, the disclosure is not limited thereto, and the number of island power tap cells placed between the first and second inline power tap cells 71 and 72 may change depending on implementations. Also, although FIG. 11 illustrates that the island power tap cell 73 is constituted in a 3-CH, the disclosure is not limited thereto, and the height of the island power tap cell 73 in the second direction Y, that is, the number of power tap cells included in the island power tap cell 73, may change depending on implementations.

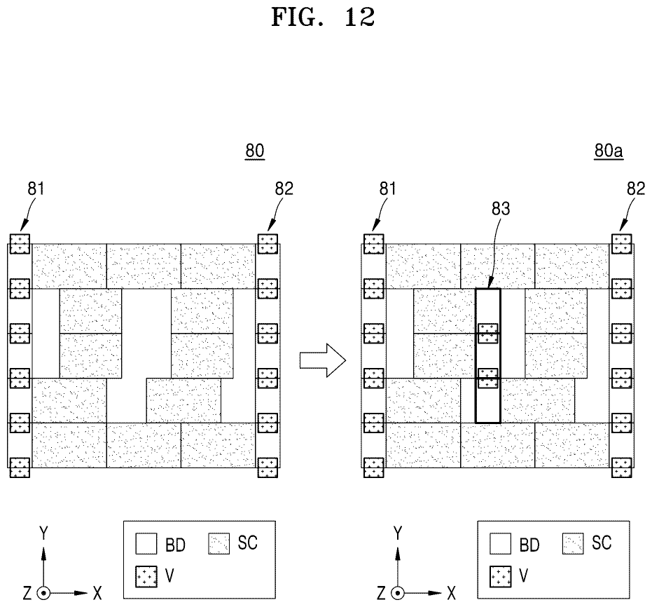

FIG. 12 illustrates a first layout 80 and a second layout 80a according to some implementations.

Referring to FIG. 12, a method of manufacturing an integrated circuit including standard cells SC may include a P&R operation and a verification operation. Through the P&R operation, the first layout 80, which includes first and second inline power tap cells 81 and 82 and the standard cells SC between the first and second inline power tap cells 81 and 82, may be generated. Thereafter, in the verification operation, IR-drop may be checked to check the power stability of the first layout 80. In this case, the second layout 80a may be generated by adding an island power tap cell 83 to a section in which the IR-drop is great.

In some implementations, the island power tap cell 83 may be placed in a free space, in which the standard cells SC are not placed, through an engineering change order (ECO). In some implementations, when a placement space for the island power tap cell 83 is insufficient, the island power tap cell 83 may be placed by adjusting the placement of some standard cells SC through the ECO. For example, a space for the island power tap cell 83 may be obtained by moving positions of some standard cells SC through the ECO.

In some implementations, in a verification operation, the island power tap cell 83 may be added to a section, in which IR-drop is vulnerable, in a region between the first and second inline power tap cells 81 and 82. Although FIG. 12 illustrates that one island power tap cell 83 is added between the first and second inline power tap cells 81 and 82, the disclosure is not limited thereto, and the number of island power tap cells between the first and second inline power tap cells 81 and 82 may change depending on implementations. Also, although FIG. 12 illustrates that the island power tap cell 83 is constituted in a 3-CH, the disclosure is not limited thereto, and the height of the island power tap cell 83 in the second direction Y, that is, the number of power tap cells included in the island power tap cell 83, may change depending on implementations.

FIGS. 13A to 13D respectively illustrate devices according to some implementations.

For example, FIG. 13A illustrates a FinFET 90a, FIG. 13B illustrates a GAAFET 90b, FIG. 13C illustrates an MBCFET 90c, and FIG. 13D illustrates a vertical field effect transistor (VFET) 90d. For the sake of convenience of illustration, each of FIGS. 13A to 13C illustrates that one of two source/drain regions is removed, and FIG. 13D illustrates a cross-section of the VFET 90d which is cut in a plane parallel to another plane formed by a second direction Y and a vertical direction Z and passing through a channel CH of the VFET 90d.

Referring to FIG. 13A, the FinFET 90a may be formed by a fin-shaped active pattern extending in a first direction X between device isolation layers STI and a gate G extending in the second direction Y. Source/drains S/D may be respectively formed on both sides of the gate G, and accordingly, a source may be spaced apart from a drain in the first direction X. An insulating layer may be between a channel CH and the gate G. In some implementations, the FinFET 90a may be formed by the gate G and a plurality of active patterns spaced apart from each other in the second direction Y.

Referring to FIG. 13B, the GAAFET 90b may be formed by active patterns, which are spaced apart from each other in the vertical direction Z and extend in the first direction X, that is, nanowires, and a gate G extending in the second direction Y. Source/drains S/D may be respectively formed on both sides of the gate G, and accordingly, a source may be spaced apart from a drain in the first direction X. An insulating layer may be between a channel CH and the gate G. The number of nanowires included in the GAAFET 90b is not limited to the number of nanowires illustrated in FIG. 13B.

Referring to FIG. 13C, the MBCFET 90c may be formed by active patterns, which are spaced apart from each other in the vertical direction Z and extend in the first direction X, that is, nanosheets, and a gate G extending in the second direction Y. Source/drains S/D may be respectively formed on both sides of a gate G, and accordingly, a source may be spaced apart from a drain in the first direction X. An insulating layer may be between a channel CH and the gate G. The number of nanosheets included in the MBCFET 90c is not limited to the number of nanosheets illustrated in FIG. 13C.

Referring to FIG. 13D, the VFET 90d includes a top source/drain T_S/D and a bottom source/drain B_S/D spaced apart from each other in the vertical direction Z with a channel CH therebetween. The VFET 90d includes a gate G surrounding the circumference of the channel CH between the top source/drain T_S/D and the bottom source/drain B_S/D. An insulating layer may be between the channel CH and the gate G.

However, the transistors according to implementations are not limited to the structures described above. For example, an integrated circuit may include a ForkFET having a structure in which a P-type transistor is close to an N-type transistor by separating nanosheets for the P-type transistor from nanosheets for the N-type transistor with a dielectric wall. Also, an integrated circuit may include not only bipolar junction transistors but also FETs, such as complementary FETs (CFETs), negative capacitance FETs (NCFETs), and carbon nanotube (CNT) FETs.

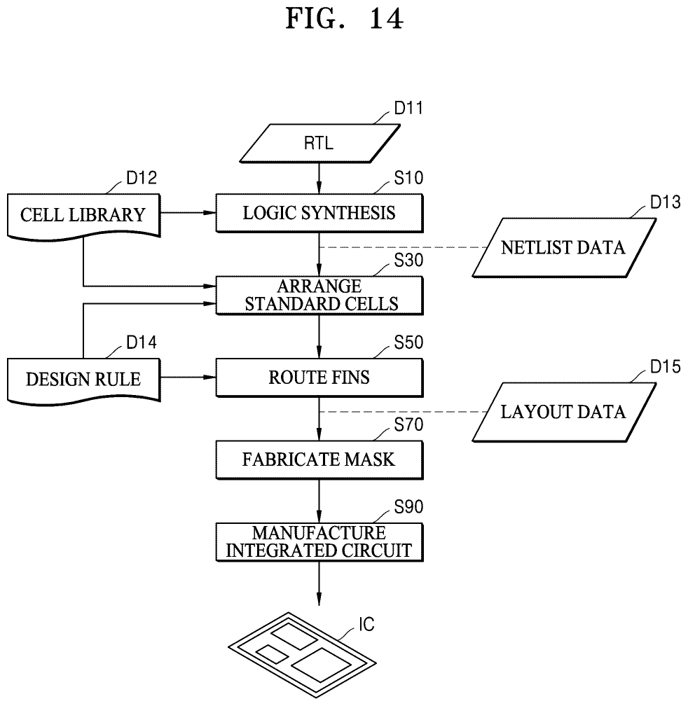

FIG. 14 is a flowchart illustrating a method of manufacturing an integrated circuit, according to some implementations.

Referring to FIG. 14, the method according to the illustrated implementations is a method of manufacturing an integrated circuit IC including standard cells and includes a plurality of operations S10, S30, S50, S70, and S90. A cell library (or a standard cell library) D12 may include information on the standard cells, for example, information on functions, characteristics, layouts, and so on. In some implementations, the cell library D12 may define tap cells and dummy cells as well as functional cells that generate output signals from input signals. In some implementations, the cell library D12 may define memory cells and dummy cells having the same footprint. A design rule D14 may include requirements that have to be complied with in a layout of the integrated circuit IC. For example, the design rule D14 may include requirements for a space between patterns in the same layer, the minimum width of a pattern, a routing direction of a wiring layer, and so on. In some implementations, the design rule D14 may define the minimum spacing in the same track of a wiring layer.

In operation S10, a logic synthesis operation of generating netlist data D13 from RTL data D11 may be performed. For example, a semiconductor design tool (e.g., a logic synthesis tool) may perform logic synthesis with reference to the cell library D12 from RTL data D11 generated as a VHSIC hardware description language (VHDL) and a hardware description language (HDL), such as Verilog, and a bitstream or the netlist data D13 including a netlist may be generated. The netlist data D13 may correspond to an input of place and routing, which is described below.

In operation S30, standard cells may be placed. For example, the semiconductor design tool (e.g., a P&R tool) may place standard cells used in the netlist data D13 with reference to the cell library D12. In some implementations, a semiconductor design tool may place the standard cells in a row extending in an X-axis direction or a Y-axis direction, and the placed standard cells may receive power from a power rail extending along boundaries of the row.

In some implementations, inline power tap cells and island power tap cells may be placed before the standard cells are placed. For example, the inline power tap cells may be placed before the standard cells are placed, and the island power tap cells may be placed in an IR-drop vulnerable section in which IR-drop is expected to be great. For example, the IR-drop vulnerable section may be expected based on a distance from the inline power tap cells, and the island power tap cells may be placed in the expected IR-drop vulnerable section. For example, the IR-drop vulnerable section may be expected based on a space between the inline power tap cells, and island power tap cells may be placed in the expected IR-drop vulnerable section. For example, the IR-drop vulnerable section may be expected based on the number of power tap cells included in the inline power tap cells, and the island power tap cells may be placed in the expected IR-drop vulnerable section.

In operation S50, pins of the standard cells may be routed. For example, the semiconductor design tool may generate interconnections electrically connecting output pins to input pins of the placed standard cells and generate layout data D15 defining the placed standard cells and the generated interconnections. The interconnections may include vias in a via layer and/or patterns in wiring layers. The wiring layers may include a front wiring layer in an upper portion of a front side of a substrate and a back wiring layer on a back surface of the substrate. The layout data D15 may have a format, such as GDSII, and may include geometric information of cells and interconnections. The semiconductor design tool may refer to the design rule D14 while routing pins of cells. The layout data D15 may correspond to an output of place and routing. Only operation S50 or both operation S30 and operation S50 may be referred to as a method of designing an integrated circuit.

In some implementations, the integrated circuit may include inline power tap cells and island power tap cells, and each power tap cell may include at least one via. At least one via may electrically connect the back wiring layer to the front wiring layer. As the island power tap cell includes a power tap cell, and termination cells, logic cells or standard cells may be freely placed on the top and/or bottom of the island power tap cell. Accordingly, the freedom of placement of cells in an integrated circuit may be increased, and performance may be increased by reducing IR-drop.

In operation S70, an operation of fabricating a mask may be performed. For example, in photolithography, optical proximity correction (OPC) for correcting distortion, such as refraction, caused by characteristics of light may be applied to the layout data D15. Patterns on a mask may be defined to form the patterns on a plurality of layers based on the data to which OPC is applied, and at least one mask (or photomask) for forming the pattern of each of the plurality of layers may be manufactured. In some implementations, a layout of the integrated circuit IC may be limitedly modified in operation S70, and the limited modification of the integrated circuit IC in operation S70 is post-processing for optimizing a structure of the integrated circuit IC and may be referred to as design polishing.

In operation S90, an operation of manufacturing the integrated circuit IC may be performed. For example, the integrated circuit IC may be fabricated by patterning a plurality of layers by using at least one mask fabricated in operation S70. A front-end-of-line (FEOL) may include, for example, planarizing and cleaning a wafer, forming trenches, forming wells, forming gate lines, and forming sources and drains. Individual elements, such as a transistor, a capacitor, and a resistor, may be formed in a substrate by the FEOL. Also, a back-end-of-line (BEOL) may include, for example, performing silicidation of a gate region, a source region, and a drain region, adding a dielectric, performing planarization, forming a hole, adding a metal layer, forming a via, forming a passivation layer, and so on. Individual elements, such as a transistor, a capacitor, and a resistor, may be interconnected to each other by the BEOL. In some implementations, a middle-of-line (MOL) may be performed between the FEOL and the BEOL, and contacts may be formed on the individual elements. Subsequently, the integrated circuit IC may be packaged in a semiconductor package and may be used as a component in various applications.

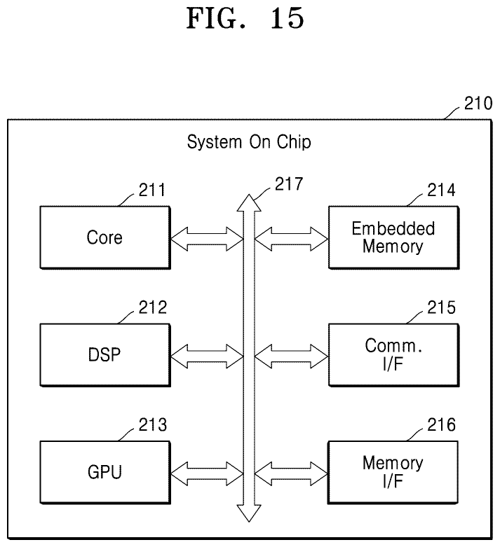

FIG. 15 is a block diagram illustrating a system-on-chip (SoC) 210 according to some implementations.

Referring to FIG. 15, the SoC 210 may refer to an integrated circuit in which components of a computing system or an electronic system are integrated. For example, an application processor (AP), for example, the SoC 210, may include a processor and components for other functions. The SoC 210 includes a core 211, a digital signal processor (DSP) 212, a graphics processing unit (GPU) 213, an embedded memory 214, a communication interface (I/F) 215, and a memory I/F 216. Components of the SoC 210 may communicate with each other through a bus 217.

The core 211 may process instructions and control operations of components included in the SoC 210. For example, the core 211 may drive an operating system and execute applications of the operating system by processing a series of instructions. The DSP 212 may generate useful data by processing digital signals, for example, the digital signals provided from the communication interface 215. The GPU 213 may generate data for an image output on a display device from image data provided from the embedded memory 214 or the memory interface 216 and may encode the image data. In some implementations, the integrated circuit described above with reference to the drawings may be included in the core 211, the DSP 212, the GPU 213, and/or the embedded memory 214.

The embedded memory 214 may store data required for the core 211, the DSP 212, and the GPU 213 to operate. The communication interface 215 may provide an interface for a communication network or one-to-one communication. The memory interface 216 may provide an interface to an external memory of the SoC 210, such as dynamic random access memory (DRAM) and flash memory.

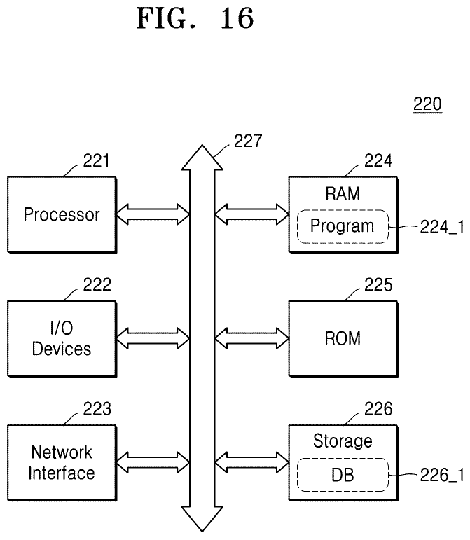

FIG. 16 is a block diagram illustrating a computing system 220 including a memory for storing a program, according to some implementations.

Referring to FIG. 16, in a method of designing an integrated circuit according to some implementations, for example, at least some of the operations in the flowchart described above may be performed by the computing system 220. The computing system 220 includes a processor 221, input/output (I/O) devices 222, a network interface 223, random access memory (RAM) 224, read only memory (ROM) 225, and a storage 226. The processor 221, the I/O devices 222, the network interface 223, the RAM 224, the ROM 225, and the storage 226 may be connected to a bus 227 and may communicate with each other through the bus 227.

The processor 221 may be referred to as a processing unit and may include at least one core, which may perform any instruction set (e.g., Intel Architecture-32 (IA-32), 64-bit-extended IA-32, x86-64, PowerPC, Sparc, MIPS, ARM, IA-64, and so on), such as a micro-processor, an AP, a DSP, or a GPU. For example, the processor 221 may access a memory, that is, the RAM 224 or the ROM 225, via the bus 227 and may perform instructions stored in the RAM 224 and the ROM 225.

The RAM 224 may store a program 224_1 or at least a part thereof for a method of designing an integrated circuit, according to some implementations, and the program 224_1 may cause the processor 221 to perform the method of designing an integrated circuit, for example, at least some of the operations included in the method of FIG. 14. That is, the program 224_1 may include a plurality of instructions executable by the processor 221, and the plurality of instructions included in the program 224_1 may cause the processor 221 to perform at least some of the operations included in, for example, the flowcharts described above.

The storage 226 may not lose stored data even when the power supplied to the computing system 220 is off. The storage 226 may store the program 224_1 according to some implementations, and before the program 224_1 is executed by the processor 221, the program 224_1 or at least a part thereof may be loaded into the RAM 224 from the storage 226. Alternatively, the storage 226 may store a file written in a programming language, and the program 224_1 generated from the file by a compiler or the like or at least a part thereof may be loaded into the RAM 224. Also, the storage 226 may store a database (DB) 226_1, and the database 226_1 may include information required for designing an integrated circuit, for example, information on designed blocks, the cell library D12 of FIG. 14, and/or the design rule D14.

The storage 226 may also store data to be processed by the processor 221 or data processed by the processor 221. That is, the processor 221 may generate data by processing the data stored in the storage 226 according to the program 224_1 and also store the generated data in the storage 226. For example, the storage 226 may store the RTL data D11, the netlist data D13, and/or the layout data D15 of FIG. 14.

The I/O devices 222 may include an input device, such as a keyboard or a pointing device, and include an output device, such as a display device or a printer. For example, a user may also trigger execution of the program 224_1 by using the processor 221 through the I/O devices 222, also read the RTL data D11 and/or the netlist data D13 of FIG. 14, and also check the layout data D15 of FIG. 14. The network interface 223 may provide access to an external network of the computing system 220. For example, the external network may include multiple computing systems and communication links, and the communication links may include wired links, optical links, wireless links, or any other type of links.

As described above, implementations are disclosed in the drawings and specification. Although implementations are described in the disclosure by using certain terms, this is used only for the purpose of describing the technical idea of the disclosure and is not used to limit the meaning or scope of the disclosure as set forth in the claims. Therefore, those skilled in the art will understand that various modifications and other equivalent implementations may be derived therefrom. Therefore, the true technical protection scope of the disclosure should be determined by the technical idea of the attached patent claims.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

While the disclosure has been particularly shown and described with reference to implementations thereof, it will be understood that various changes in form and details may be made therein without departing from the spirit and scope of the following claims.

What is claimed is:

1. An integrated circuit comprising:
a plurality of active patterns including a first active pattern and a second active pattern, wherein the first active pattern and the second active pattern each extend in a first direction and are spaced apart from each other in a second direction intersecting with the first direction;
a front wiring layer arranged above a front side of a substrate;
a back wiring layer arranged on a backside of the substrate; and
an island power tap cell arranged on the front side of the substrate,
wherein the island power tap cell comprises a first termination cell and a second termination cell spaced apart from each other in the second direction, and comprises a power tap cell arranged between the first and second termination cells and electrically connecting the back wiring layer to the front wiring layer, and
wherein the first active pattern is cut above the first termination cell, and the second active pattern is cut above the second termination cell.

2. The integrated circuit of claim 1, wherein
the plurality of active patterns further comprise a third active pattern that is adjacent to the first active pattern and overlaps the first termination cell, and a fourth active pattern that is adjacent to the second active pattern and overlaps the second termination cell, and
the third active pattern and the fourth active pattern are configured as dummy patterns.

3. The integrated circuit of claim 1, further comprising:
a cutting layer that cuts at least one active pattern of the plurality of active patterns,
wherein the at least one active pattern overlaps the island power tap cell, and
wherein the first and second active patterns are respectively cut above the first and second termination cells by the cutting layer.

4. The integrated circuit of claim 3, wherein the cutting layer overlaps a partial region of the first termination cell, overlaps the power tap cell, and overlaps a partial region of the second termination cell.

5. The integrated circuit of claim 3, wherein a height of the cutting layer in the second direction corresponds to twice a height of the power tap cell in the second direction.

6. The integrated circuit of claim 3, wherein
the plurality of active patterns further include at least one fifth active pattern overlapping the power tap cell, and
the at least one fifth active pattern is cut above the power tap cell by the cutting layer.

7. The integrated circuit of claim 1, wherein the power tap cell includes a plurality of power tap cells arranged in the second direction.

8. The integrated circuit of claim 1, wherein each active pattern of the plurality of active patterns comprises at least one of a fin, a nanowire, and a nanosheet.

9. The integrated circuit of claim 1, wherein
the front wiring layer includes a first front wiring line and a second front wiring line,
the back wiring layer includes a first back wiring pattern and a second back wiring pattern, and
the power tap cell includes at least one of a first via extending vertically between the first front wiring line and the first back wiring pattern, or a second via extending vertically between the second front wiring line and the second back wiring pattern.

10. The integrated circuit of claim 1, wherein the power tap cell is configured to transfer a positive supply voltage from the back wiring layer to the front wiring layer.

11. The integrated circuit of claim 1, wherein the power tap cell is configured to transfer a negative supply voltage from the back wiring layer to the front wiring layer.

12. An integrated circuit comprising:
a plurality of active patterns including a first active pattern and a second active pattern, wherein the first active pattern and the second active pattern each extend in a first direction and are spaced apart from each other in a second direction intersecting with the first direction;
a front wiring layer arranged above a front side of a substrate;
a back wiring layer arranged on a backside of the substrate;
a plurality of first inline power tap cells arranged in a row in the second direction;
a plurality of second inline power tap cells arranged in a row in the second direction and spaced apart from the plurality of first inline power tap cells in the first direction; and
an island power tap cell arranged between the plurality of first inline power tap cells and the plurality of second inline power tap cells,
wherein the island power tap cell comprises a first termination cell and a second termination cell spaced apart from each other in the second direction, and comprises a power tap cell arranged between the first and second termination cells and electrically connecting the back wiring layer to the front wiring layer, and
wherein the first active pattern is cut above the first termination cell, and the second active pattern is cut above the second termination cell.

13. The integrated circuit of claim 12, further comprising a plurality of standard cells arranged between the plurality of first inline power tap cells and the island power tap cell and between the plurality of second inline power tap cells and the island power tap cell.

14. The integrated circuit of claim 12, wherein
the plurality of active patterns further comprise a third active pattern that is adjacent to the first active pattern and overlaps the first termination cell, and a fourth active pattern that is adjacent to the second active pattern and overlaps the second termination cell, and
the third active pattern and the fourth active pattern are configured as dummy patterns.

15. The integrated circuit of claim 12, further comprising:
a cutting layer that cuts at least one active pattern of the plurality of active patterns,
wherein the at least one active pattern overlaps the island power tap cell, and
wherein the first and second active patterns are respectively cut above the first and second termination cells by the cutting layer.

16. The integrated circuit of claim 15, wherein
the plurality of active patterns further include at least one fifth active pattern overlapping the power tap cell, and
the at least one fifth active pattern is cut above the power tap cell by the cutting layer.

17. The integrated circuit of claim 12, wherein the power tap cell includes a plurality of power tap cells arranged in the second direction.

18. An integrated circuit comprising:
a front wiring layer arranged above a front side of a substrate, wherein the front wiring layer includes a plurality of front wiring lines extending in a first direction;
a back wiring layer arranged on a backside of the substrate;
a plurality of first inline power tap cells arranged in a row in a second direction intersecting with the first direction;
a plurality of second inline power tap cells arranged in a row in the second direction and spaced apart from the plurality of first inline power tap cells in the first direction;
a first island power tap cell arranged between the plurality of first inline power tap cells and the plurality of second inline power tap cells; and
a second island power tap cell arranged between the plurality of first inline power tap cells and the plurality of second inline power tap cells,
wherein a height of the first island power tap cell in the second direction is different from a height of the second island power tap cell in the second direction.

19. The integrated circuit of claim 18, wherein
the first island power tap cell comprises a first termination cell and a second termination cell spaced apart from each other in the second direction, and comprises a power tap cell arranged between the first and second termination cells and electrically connecting the back wiring layer to the front wiring layer, and
the second island power tap cell comprises a third termination cell and a fourth termination cell spaced apart from each other in the second direction, and comprises a plurality of power tap cells arranged between the third and fourth termination cells and electrically connecting the back wiring layer to the front wiring layer.

20. The integrated circuit of claim 19, further comprising:
a plurality of active patterns extending in the first direction and spaced apart from each other in the second direction;
a first cutting layer that cuts at least one first active pattern of the plurality of active patterns, wherein the at least one first active pattern overlaps the first island power tap cell; and
a second cutting layer that cuts at least one second active pattern of the plurality of active patterns, wherein the at least one second active pattern overlaps the second island power tap cell.
